(19) United States
(12) Patent Application Publication
(10) Pub. No.: US 2025/0258262 A1
(43) Pub. Date: Aug. 14, 2025

(54) METHOD AND SYSTEM FOR ENHANCED ACCELERATION OF MRI SCANS USING HADAMARD EXCITATION

(71) Applicant: GE Precision Healthcare LLC, Waukesha, WI (US)

(72) Inventors: Sudhir Ramanna, Bangalore (IN); Ramesh Venkatesan, Bangalore (IN); Nitin Jain, Bangalore (IN); Harsh Agarwal, Bangalore (IN)

(21) Appl. No.: 18/938,603

(22) Filed: Nov. 6, 2024

Related U.S. Application Data
(60) Provisional application No. 63/553,270, filed on Feb. 14, 2024.

(51) Int. Cl. G01R 33/561; G01R 33/483; G01R 33/56

(52) U.S. Cl. CPC G01R 33/5616; G01R 33/4835; G01R 33/5608

(57) ABSTRACT

A computer-implemented method for generating a magnetic resonance (MR) image of an object includes applying, via a processing system comprising one or more processors, a Hadamard encoded radiofrequency (RF) excitation pulse sequence to adjacent slices within a magnetic resonance imaging (MRI) scanner to generate Hadamard encoded adjacent slices; multiplexing, via the processing system, the Hadamard encoded adjacent slices with secondary RF excitation pulses to generate a composite RF pulse; and generating, via the processing system, the MR image of the object using the composite RF pulse.

### CROSS-REFERENCE TO RELATED APPLICATION

This application claims priority to and the benefit of U.S. Provisional Application No. 63/553,270, entitled “SYSTEMS AND METHODS FOR ENHANCED ACCELERATION OF MRI SCANS USING HADAMARD EXCITATION”, filed Feb. 14, 2024, which is herein incorporated by reference in its entirety for all purposes.

### BACKGROUND

Embodiments disclosed in the present invention relate to medical imaging technologies, and more specifically to a method for obtaining magnetic resonance imaging (MRI) data and a magnetic resonance imaging system.

Magnetic Resonance Imaging (MRI) is a non-invasive imaging technology that produces three-dimensional detailed anatomical images without the use of damaging radiation. It is widely used for medical diagnosis, staging of disease, and for follow-up without exposure to ionizing radiation. However, one of the main challenges in MRI is the long scan time, which can lead to patient discomfort and reduced throughput for diagnostic centers.

There is a continuous demand for innovations that can provide faster MRI scans without sacrificing image quality. Reducing scan times can significantly improve the patient's experience by decreasing the anxiety associated with long and noisy scans. It also enhances motion robustness and allows diagnostic centers to accommodate more patients, thereby increasing operational efficiency and revenue.

The current state of MRI technology includes various methods to accelerate scan times and improve patient comfort. One such method is the use of Multiband (MB) technology, which allows for the simultaneous acquisition of multiple slices, thereby reducing scan times. This is often combined with parallel imaging techniques, such as Sensitivity Encoding (SENSE) and GeneRalized Autocalibrating Partially Parallel Acquisitions (GRAPPA), to further accelerate scans. However, the acceleration factors achievable with these methods are limited by signal-to-noise ratio (SNR) penalties, commonly referred to as g-factor penalties.

Simultaneous Multi-Slice (SMS) imaging is another advancement in MRI that aims to reduce scan times by acquiring multiple slices of the anatomy concurrently. However, the application of SMS has been predominantly limited to T2 and Proton Density (PD) weighted sequences. The adiabatic nature of traditional inversion pulses presents challenges when attempting to integrate them with SMS techniques, as the methods used to multiband refocus pulses are not compatible with the adiabatic inversion pulses.

The current state of the art in SMS imaging faces several challenges, including the inability to effectively apply SMS to inversion prepared sequences, the complexity of multiband techniques, and the need for specialized hardware. These limitations result in longer scan times and reduced patient throughput, which can be particularly burdensome in clinical settings where efficiency and patient comfort are paramount.

Therefore, a novel solution that can overcome the limitations of existing technologies and further accelerate MRI scans would be highly beneficial to both patients and healthcare providers.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a computer-implemented method for generating a magnetic resonance (MR) image of an object is provided. The computer-implemented method includes applying, via a processing system comprising one or more processors, a Hadamard encoded radiofrequency (RF) excitation pulse sequence to adjacent slices within a magnetic resonance imaging (MRI) scanner to generate Hadamard encoded adjacent slices; multiplexing, via the processing system, the Hadamard encoded adjacent slices with secondary RF excitation pulses to generate a composite RF pulse; and generating, via the processing system, the MR image of the object using the composite RF pulse.

In another embodiment, a system for generating a magnetic resonance (MR) image of an object is provided. The system includes a memory encoding processor-executable routines. The system also includes a processing system including one or more processors and configured to access the memory and to execute the processor-executable routines, wherein the processor-executable routines, when executed by the processing system, cause the processing system to perform actions. The actions include applying a Hadamard encoded radiofrequency (RF) excitation pulse sequence to adjacent slices within a magnetic resonance imaging (MRI) scanner to generate Hadamard encoded adjacent slices. The actions also include multiplexing the Hadamard encoded adjacent slices with secondary RF excitation pulses to generate a composite RF pulse. The actions further include generating the MR image of the object using the composite RF pulse.

In a further embodiment, a non-transitory computer-readable medium is provided. The non-transitory computer-readable medium includes processor-executable code that when executed by a processing system including one or more processors, causes the processing system to perform actions. The actions include applying a Hadamard encoded radiofrequency (RF) excitation pulse sequence to adjacent slices within a magnetic resonance imaging (MRI) scanner to generate Hadamard encoded adjacent slices. The actions also include multiplexing the Hadamard encoded adjacent slices with secondary RF excitation pulses to generate a composite RF pulse. The actions further include generating the MR image of the object using the composite RF pulse.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a schematic diagram of a magnetic resonance imaging (MRI) system, in accordance with aspects of the present disclosure;

FIG. 2 is a flow chart of a method for generating images using the Hadamard encoded pulses, in accordance with aspects of the present disclosure;

FIGS. 3A-3C illustrate a comparison of various pulse sequence diagrams (utilizing Hadamard encoded pulses and multibanding), in accordance with aspects of the present disclosure;

FIG. 4A and FIG. 4B illustrate two sets of pulse sequence diagrams (utilizing Hadamard encoded pulses and inversion recovery (IR) sequence), in accordance with aspects of the present disclosure;

FIG. 5 depicts an axial images of a fat/water phantom, in accordance with aspects of the present disclosure; and

FIG. 6 depicts a comparison of images acquired of a knee of a subject, in accordance with aspects of the present disclosure.

### DETAILED DESCRIPTION

One or more specific embodiments will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present embodiments, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments. Furthermore, the terms “circuit” and “circuitry” and “controller” may include either a single component or a plurality of components, which are either active and/or passive and are connected or otherwise coupled together to provide the described function.

In magnetic resonance imaging (MRI), an object is placed in a magnet. When the object is in the magnetic field generated by the magnet, magnetic moments of nuclei, such as protons, attempt to align with the magnetic field but process about the magnetic field in a random order at the nuclei's Larmor frequency. The magnetic field of the magnet is referred to as B0 and extends in the longitudinal or z direction. In acquiring a MR image, a magnetic field (referred to as an excitation field B1), which is in the x-y plane and near the Larmor frequency, is generated by a radio-frequency (RF) coil and may be used to rotate, or “flip,” the net magnetic moment (or net magnetization) M_{z} of the nuclei from the z direction to the transverse or x-y plane. This flip of the net magnetic moment M_{z} of the nuclei is measured by a flip angle which is the amount of rotation the net magnetization experiences during the application of the RF pulse to the RF coil. A signal, which is referred to as a MR signal, is emitted by the nuclei, after the excitation signal B1 is terminated. To use the MR signals to generate an image of an object, magnetic field gradient pulses (Gₓ, G_{y}, and G_{z}) are used. The gradient pulses are used to scan through the k space, the space of spatial frequencies or inverse of distances. A Fourier relationship exists between the acquired MR signals and an image of the object, and therefore the image of the object can be derived by reconstructing the MR signals. The images of the object may include two dimensional (2D) or three-dimensional (3D) images.

The present disclosure provides for systems and methods for accelerating the generation of MR images of an object (e.g., patient) utilizing a combination of multiband technology and Hadamard excitation. The disclosed embodiments include systems and methods for generating an image of an object. The systems and methods include applying a Hadamard encoded radiofrequency (RF) excitation pulse sequence to adjacent slices within a magnetic resonance imaging (MRI) scanner to generate Hadamard encoded adjacent slices. The systems and methods include multiplexing the Hadamard encoded adjacent slices with secondary RF excitation pulses to generate a composite RF pulse. The systems and methods include generating the MR image of the object using the composite RF pulse.

In certain embodiments, the secondary RF excitation pulses include multiband RF excitation pulses or an inversion recovery (IR) sequence. In certain embodiments, the secondary RF excitation pulses include the multiband RF excitation pulses, and the Hadamard encoded RF excitation pulse sequence and the multiband RF excitation pulses are frequency multiplexed using the Larmor frequency of nearby slices for the Hadamard encoded RF excitation pulses and the Larmor frequency of far-away slices for the multiband RF excitation pulses. In certain embodiments, the secondary RF excitation pulses include the IR sequence, and the IR sequence employs an increased slice thickness for the purpose of inverting or preparing the Hadamard encoded adjacent slices. In certain embodiments, the IR sequence is followed by Hadamard encoded Cartesian or Propeller or Radial or Spiral readout. In certain embodiments, the secondary RF excitation pulses include the IR sequence, and the IR sequence employs an adiabatic or non-adiabatic pulse to invert or prepare the Hadamard encoded adjacent slices. In certain embodiments, the composite RF pulse is employed to accelerate a diffusion, perfusion or functional MRI scans with echo planar imaging (EPI) readout. In certain embodiments, the systems and methods include utilizing parallel imaging techniques with the composite RF pulse to increase total acceleration factors of the MRI scan. In certain embodiments, the parallel imaging techniques include at least one of Autocalibrating Reconstruction for Cartesian imaging (ARC), GeneRalized Autocalibrating Partially Parallel Acquisitions (GRAPPA), Sensitivity Encoding (SENSE), Array coil Spatial Sensitivity Encoding (ASSET) or Compressed Sensing. In certain embodiments, the systems and methods include applying a slice selection gradient for refocusing pulses that is half the regular slice gradient. In certain embodiments, the systems and methods include decoding the Hadamard encoded pulses and the secondary encoded pulses in a reconstruction process to produce a composite magnetic resonance (MR) signal. In certain embodiments, the systems and methods include utilizing a pair of simultaneous multi-slice (SMS) with the composite RF pulse to increase total acceleration factors of the MRI scan. In certain embodiments, the SMS excited slices are encoded and decoded using Hadamard or Hadamard-like factors. In certain embodiments, the encoding and decoding is performed using a single average or multiple averages for Hadamard encoding and decoding.

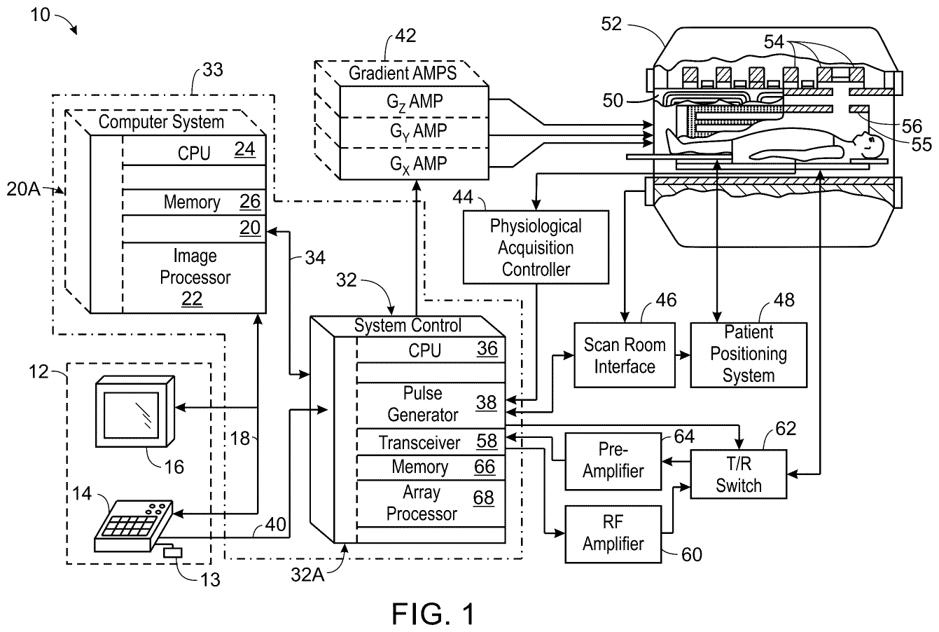

Embodiments of the present disclosure will now be described, by way of an example, with reference to the figures, in which FIG. 1 is a schematic diagram of a magnetic resonance imaging (MRI) system 10. Operation of the system 10 may be controlled from an operator console 12, which includes an input device 13, a control panel 14, and a display screen 16. The input device 13 may be a mouse, joystick, keyboard, track ball, touch activated screen, light wand, voice control, and/or other input device. The input device 13 may be used for interactive geometry prescription. The console 12 communicates through a link 18 with a computer system 20 that enables an operator to control the production and display of images on the display screen 16. The link 18 may be a wireless or wired connection. The computer system 20 may include modules that communicate with each other through a backplane 20a. The modules of the computer system 20 may include an image processor module 22, a central processing unit (CPU) module 24, and a memory module 26 that may include a frame buffer for storing image data arrays, for example. The computer system 20 may be linked to archival media devices, permanent or back-up memory storage or a network for storage of image data and programs and communicates with MRI system control 32 through a high-speed signal link 34. The MRI system control 32 may be separate from or integral with the computer system 20. The computer system 20 and the MRI system control 32 collectively form an “MRI controller” 33 or “controller”.

In the exemplary embodiment, the MRI system control 32 includes modules connected by a backplane 32a. These modules include a CPU module 36, a calibration module 37 as well as a pulse generator module 38. The CPU module 36 connects to the operator console 12 through a data link 40. The MRI system control 32 receives commands from the operator through the data link 40 to indicate the scan sequence that is to be performed. The CPU module 36 operates the system components to carry out the desired scan sequence and produces data which indicates the timing, strength and shape of the RF pulses produced, and the timing and length of the data acquisition window. The CPU module 36 connects to components that are operated by the MRI controller 32, including the pulse generator module 38 which controls a gradient amplifier 42, a physiological acquisition controller (PAC) 44, and a scan room interface circuit 46.

In one example, the CPU module 36 receives patient data from the physiological acquisition controller 44, which receives signals from sensors connected to the object, such as ECG signals received from electrodes attached to the patient. As used herein, an object is a human (or patient), an animal, or a phantom. The CPU module 36 receives, via the scan room interface circuit 46, signals from the sensors associated with the condition of the patient and the magnet system. The scan room interface circuit 46 also enables the MRI controller 33 to command a patient positioning system 48 to move the patient to a desired position for scanning.

A whole-body RF coil 56 is used for transmitting the waveform towards subject anatomy. The whole body-RF coil 56 may be a body coil. An RF coil may also be a local coil that may be placed in more proximity to the subject anatomy than a body coil. The RF coil 56 may also be a surface coil. RF coils containing RF receiver channels may be used for receiving the signals from the subject anatomy. Typical surface coil would have eight receiving channels; however, different number of channels are possible. Using the combination of both a body coil 56 and a surface coil is known to provide better image quality.

The pulse generator module 38 may operate the gradient amplifiers 42 to achieve desired timing and shape of the gradient pulses that are produced during the scan. The gradient waveforms produced by the pulse generator module 38 may be applied to the gradient amplifier system 42 having Gx, Gy, and Gz amplifiers. Each gradient amplifier excites a corresponding physical gradient coil in a gradient coil assembly 50, to produce the magnetic field gradients used for spatially encoding acquired signals. Specifically, Gx corresponds to a flow/frequency encoding gradient, Gy corresponds to a phase encoding gradient and Gz corresponds to a slice select gradient. The gradient coil assembly 50 may form part of a magnet assembly 52, which also includes a polarizing magnet 54 (which, in operation, provides a longitudinal magnetic field Bo throughout a target volume 55 that is enclosed by the magnet assembly 52 and a whole-body RF coil 56 (which, in operation, provides a transverse magnetic field B1 that is generally perpendicular to B0 throughout the target volume 55. A transceiver module 58 in the MRI system control 32 produces pulses that may be amplified by an RF amplifier 60 and coupled to the RF coil 56 by a transmit/receive switch 62. The resulting signals emitted by the excited nuclei in the subject anatomy may be sensed by receiving coils (not shown) and provided to a preamplifier 64 through the transmit/receive switch 62. The amplified MR signals are demodulated, filtered, and digitized in the receiver section of the transceiver 58. The transmit/receive switch 62 is controlled by a signal from the pulse generator module 38 to electrically connect the RF amplifier 60 to the coil 56 during the transmit mode and to connect the preamplifier 64 to the receiving coil during the receive mode.

The MR signals produced from excitation of the target are digitized by the transceiver module 58. The MR system control 32 then processes the digitized signals by Fourier transform to produce k-space data, which is transferred to a memory module 66, or other computer readable media, via the MRI system control 32. “Computer readable media” may include, for example, structures configured so that electrical, optical, or magnetic states may be fixed in a manner perceptible and reproducible by a conventional computer (e.g., text or images printed to paper or displayed on a screen, optical discs, or other optical storage media, “flash” memory, EEPROM, SDRAM, or other electrical storage media; floppy or other magnetic discs, magnetic tape, or other magnetic storage media).

A scan is completed when an array of raw k-space data has been acquired in the computer readable media 66. This raw k-space data is rearranged into separate k-space data arrays for each image to be reconstructed, and each of these k-space data arrays is input to an array processor 68, which operates to reconstruct the data into an array of image data, using a reconstruction algorithm such as a Fourier transform. When the full k-space data is obtained, it represents the entire volume of the subject body and the k-space so obtained may be referred as the reference k-space. Similarly, when only the partial k-space data is obtained, the image may be referred as the partial k-space. This image data is conveyed through the data link 34 to the computer system 20 and stored in memory. In response to the commands received from the operator console 12, this image data may be archived in a long-term storage or may be further processed by the image processor 22 and conveyed to the operator console 12 and presented on the display 16.

MR signals are represented by complex numbers, where each location at the k-space is represented by a complex number, with I and Q quadrature MR signals being the real and imaginary components. Complex MR images may be reconstructed based on I and Q quadrature MR signals, using processes such as Fourier transform of the k-space MR data. Complex MR images are MR images with each pixel represented by a complex number, which also has a real component and an imaginary component. The magnitude M of the received MR signal may be determined as the square root of the sum of the squares of the I and Q quadrature components of the received MR signal as in Eq. (3) below:

$$M = \sqrt{{I}^{2} + {Q}^{2}} \qquad ( 1 )$$

and the phase ϕ of the received MR signal may also be determined as in eq. (2) below:

$$ϕ = {tan}^{- 1} ( \frac{Q}{I} ) . \qquad ( 2 )$$

Scan times in MRI are long and noisy. This discourages both the patient and the customer. Multiplexing the slices to reduce scan time helps to reduce the anxiety levels of the patient, motion robustness of the scans and accommodating more patients in the same day for the diagnostic centers.

Current multiband technology combined with parallel imaging techniques helps to accelerate scans, but the acceleration factors are limited by g-factor penalties. In one embodiment, a technique is presented that can further accelerate multiband scans and work with parallel imaging by supplementing using Hadamard excitation in a single pulse sequence.

Multiplexing the slices to reduce scan time helps to reduce the anxiety levels of the patient, motion robustness of the scans and accommodating more patients in the same day for the diagnostic centers. Increasing the acceleration factors helps everyone in the imaging pipeline.

As described in greater detail below, the CPU module 36 or other computing component of the MRI system 10 (having a processing system including one or more processors executing instructions stored in a memory) is configured to generate a magnetic resonance (MR) image of an object. The CPU module 36 is configured to apply a Hadamard encoded radiofrequency (RF) excitation pulse sequence to adjacent slices within a magnetic resonance imaging (MRI) scanner to generate Hadamard encoded adjacent slices. The CPU module 36 is also configured to multiplex the Hadamard encoded adjacent slices with secondary RF excitation pulses to generate a composite RF pulse. The CPU module is further configured to generate the MR image of the object using the composite RF pulse.

In certain embodiments, the secondary RF excitation pulses include multiband RF excitation pulses or an inversion recovery (IR) sequence. In certain embodiments, the secondary RF excitation pulses include the multiband RF excitation pulses, and wherein the Hadamard encoded RF excitation pulse sequence and the multiband RF excitation pulses are frequency multiplexed using the Larmor frequency of nearby slices for the Hadamard encoded RF excitation pulses and the Larmor frequency of far-away slices for the multiband RF excitation pulses. In certain embodiments, the secondary RF excitation pulses include the IR sequence, and wherein the IR sequence employs an increased slice thickness for the purpose of inverting or preparing the Hadamard encoded adjacent slices. In certain embodiments, the IR sequence is followed by Hadamard encoded Cartesian or Propeller or Radial or Spiral readout. In certain embodiments, wherein the secondary RF excitation pulses include the IR sequence, the IR sequence employs an adiabatic or non-adiabatic pulse to invert or prepare the Hadamard encoded adjacent slices. In certain embodiments, the composite RF pulse is employed to accelerate a diffusion, perfusion or functional MRI scans with echo planar imaging (EPI) readout.

In certain embodiments, the CPU module 36 is configured to utilize parallel imaging techniques with the composite RF pulse to increase total acceleration factors of the MRI scan. In certain embodiments, the parallel imaging techniques include at least one of Autocalibrating Reconstruction for Cartesian imaging (ARC), GeneRalized Autocalibrating Partially Parallel Acquisitions (GRAPPA), Sensitivity Encoding (SENSE), Array coil Spatial Sensitivity Encoding (ASSET) or Compressed Sensing.

In certain embodiments, the CPU module 36 is configured to apply a slice selection gradient for refocusing pulses that is half the regular slice gradient. In certain embodiments, the CPU module is configured to decode the Hadamard encoded pulses and the secondary encoded pulses in a reconstruction process to produce a composite magnetic resonance (MR) signal. In certain embodiments, the CPU module 36 is configured to utilize a pair of simultaneous multi-slice (SMS) with the composite RF pulse to increase total acceleration factors of the MRI scan. In certain embodiments, the SMS excited slices are encoded and decoded using Hadamard or Hadamard-like factors. In certain embodiments, the encoding and decoding is performed using a single average or multiple averages for Hadamard encoding and decoding.

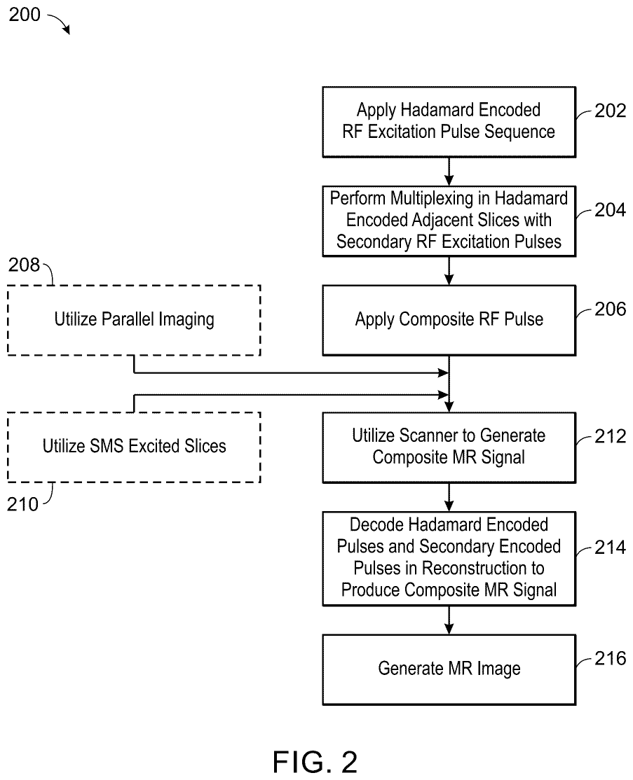

FIG. 2 shows a flow chart of a method 200 for generating images using the Hadamard encoded pulses in accordance with an embodiment of the present technique. One or more steps of the method 200 may be performed by one or more components of the MRI system 10 in FIG. 1 (e.g., CPU module 36). The method 200 includes applying Hadamard encode in pulse sequence diagram (block 202). In particular, a Hadamard encoded radiofrequency (RF) excitation pulse sequence is applied to adjacent slices within a magnetic resonance imaging (MRI) scanner to generate Hadamard encoded adjacent slices. The method 200 also includes performing multiplexing in the Hadamard encoded adjacent slices with secondary RF excitation pulses to generate a composite RF pulse (block 204).

In certain embodiments, a multiband encode technique is applied in the pulse sequence diagram (i.e., the secondary RF excitation pulses are multiband RF excitations pulses). In certain embodiments, a slice selection gradient is applied for refocusing pulses that is half the regular slice gradient. In certain embodiments, the Hadamard encoded RF excitation pulse sequence and the multiband RF excitation pulses are frequency multiplexed using the Larmor frequency of nearby slices for the Hadamard encoded RF excitation pulses and the Larmor frequency of far-away slices for the multiband RF excitation pulses.

In certain embodiments, the secondary RF excitation pulses are an inversion recovery (IR) sequence. In certain embodiments, the IR sequence employs an increased slice thickness for the purpose of inverting or preparing the Hadamard encoded adjacent slices. In certain embodiments, the IR sequence is followed by Hadamard encoded Cartesian or Propeller or Radial or Spiral readout. In certain embodiments, the IR sequence employs an adiabatic or non-adiabatic pulse to invert or prepare the Hadamard encoded adjacent slices.

The method 200 also includes applying a composite RF pulse to generate an MR image of the object using the composite RF pulse (block 206). In certain embodiments, the composite RF pulse is employed to accelerate a diffusion scan, a perfusion scan, or a functional MRI scan with echo planar imaging (EPI) readout.

In certain embodiments, the method 200 includes utilizing parallel imaging techniques with the composite RF pulse to increase total acceleration factors of the MRI scan (block 208). In certain embodiments, the parallel imaging techniques include at least one of Autocalibrating Reconstruction for Cartesian imaging (ARC), GeneRalized Autocalibrating Partially Parallel Acquisitions (GRAPPA), Sensitivity Encoding (SENSE), Array coil Spatial Sensitivity Encoding (ASSET) or Compressed Sensing.

In certain embodiments, the method 200 includes utilizing a pair of simultaneous multi-slice (SMS) excited slices with the composite RF pulse to increase total acceleration factors of the MRI scan (block 210). The SMS excited slices are encoded and decoded using Hadamard or Hadamard-like factors. The encoding and decoding is performed using a single average or multiple averages for Hadamard encoding and decoding.

Using these pulses, the method 200 includes utilizing the MR scanner to generate a composite MR signal (block 212). The method 200 also includes decoding the Hadamard encoded pulses and the secondary encoded pulses in a reconstruction process to produce the composite MR signal (block 214). The method 200 further includes generating an MR image of the subject utilizing the composite MR signal (block 216).

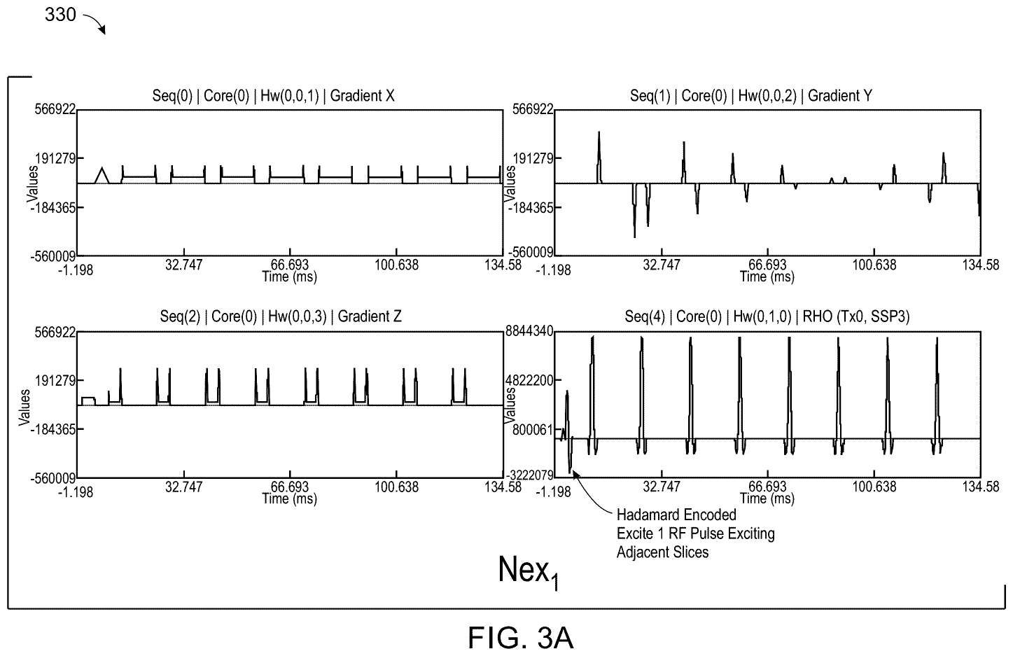

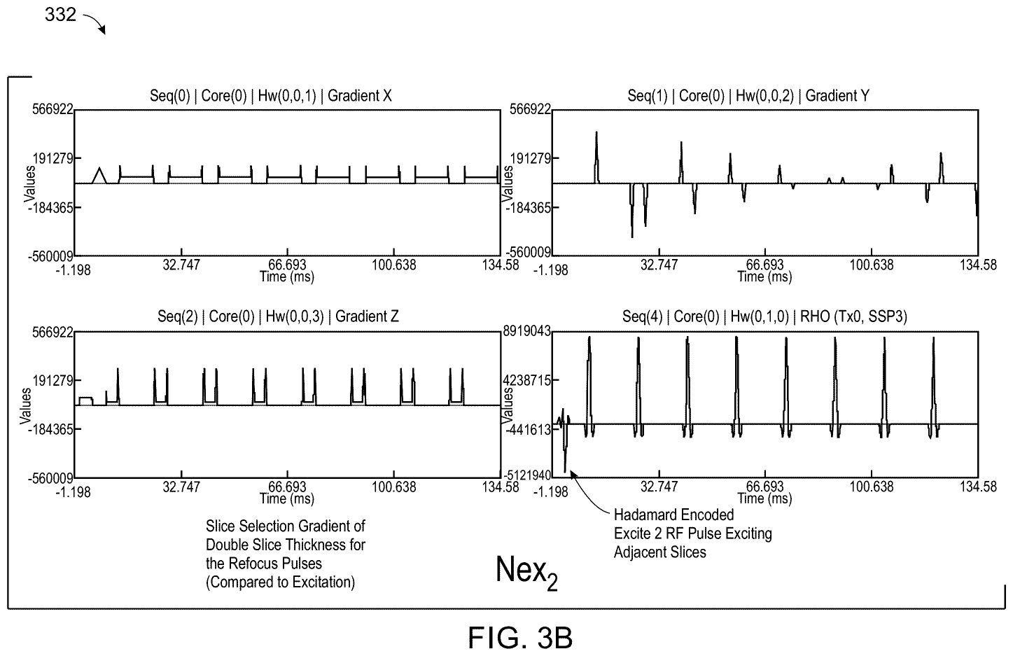

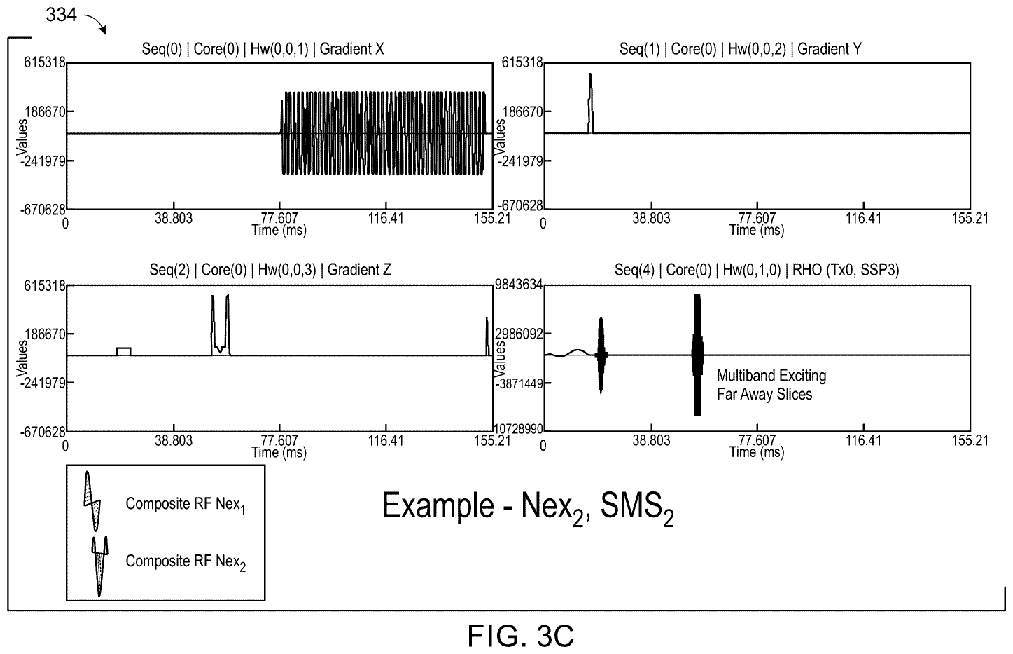

FIGS. 3A-3C illustrate a comparison of various pulse sequence diagrams (utilizing Hadamard encoded pulses and multibanding). Specifically, FIGS. 3A-3C shows three sets of pulse diagrams 330, 332 and 334 corresponding to NEX1 (single acquisition), NEX2 (double acquisition), and NEX2 simultaneous multi-slice (SMS) acquisition, respectively. Each pulse diagram 330, 332, and 334 includes x, y, z gradient waveforms and corresponding spin-lattice relaxation (T1ρ) with parallel imaging and second simultaneous multi-slice acquisition (SSP3). Pulse diagrams 330 and 332 also show Hadamard Encoded pulses and pulse diagram 334 shows multiband exciting far away pulses.

In general, in one embodiment, a technique is proposed to multiband the Hadamard encoded pulses with parallel imaging to increase the total acceleration factors. Hadamard like encoding pulses can also work along similar lines with multiband and parallel imaging. Both multiband and Hadamard encoding are frequency multiplexing the RF pulses. Multiband pulses are using the Larmor frequency of far-away slices to generate a composite RF pulse. Hadamard uses the Larmor frequency of nearby slices to generate a composite RF pulse. Readout and other gradients are similar to existing sequences. Slice selection gradient of refocus pulse is half the regular slice gradient.

This technique of multibanding a Hadamard encoded pulse with parallel imaging could be very useful to speed up diffusion prepared scans, perfusion scans or functional MRI scans that use single shot or dual shot echo planar imaging.

Multibanding excitation and refocusing pulses are known to achieve slice accelerations. Parallel imaging (Asset, ARC, Grappa, Sense, Compressed sensing) is known to achieve in-plane accelerations. Multiband with parallel imaging works with ARC/Grappa. Hadamard and Hadamard like techniques can achieve slice accelerations. Hadamard with parallel imaging works with ARC/Grappa. In this idea, we are proposing to use Hadamard RF pulse to excite adjacent slices followed by multibanding the resultant pulse and then apply parallel imaging to achieve total accelerations.

In another embodiment, the key idea of using Hadamard RF pulse to excite adjacent slices can be applied to a regular inversion recovery (IR) sequence as well. Inversion Recovery is a commonly used technique to increase the T1 grey/white matter contrast. However, these pulses are usually adiabatic with not much flexibility in their flip angles. So, these pulses have increased SAR (specific absorption ratio) compared to other RF excite or refocus pulses.

Simultaneous multi slices (SMS) is a technique employed to reduce the scan time of a sequence. Its usage is limited to T2/PD weighted sequences, primarily because the adiabatic pulse does not lend itself compatible to multiband. Techniques employed to multiband the refocus pulse (like gradient verse, reduced flips) cannot be employed due to the adiabatic nature of IR pulses.

Thus, in one embodiment, with the SMS Hadamard and non-Hadamard factors, we excite multiple slices that are adjacent to each other during the acquisition. The slice separation of simultaneously excited slices is taken care of in the reconstruction stage using linear algebra techniques. In this technique, we show how IR pulses can be made adept to the SMS technique when excited with Hadamard/non-Hadamard factors.

Using this technique, T1 weighted or IR prepared sequences could also be used for SMS to help reduce scan time/increase SNR in these sequences. T1 prepped sequences are used in both pre-contrast and post-contrast exams to identify patient abnormalities. So, if these sequences are benefitted with reduction in scan time/increase in SNR, the end user/customer is benefitted with reduced scan sessions per patient and the patient is benefitted the most as he spends lesser time inside the MR bore. The technique can be used with both 2D as well as 3D sequences with IR pulses exciting multiple slices in 2D or multiple slabs in 3D.

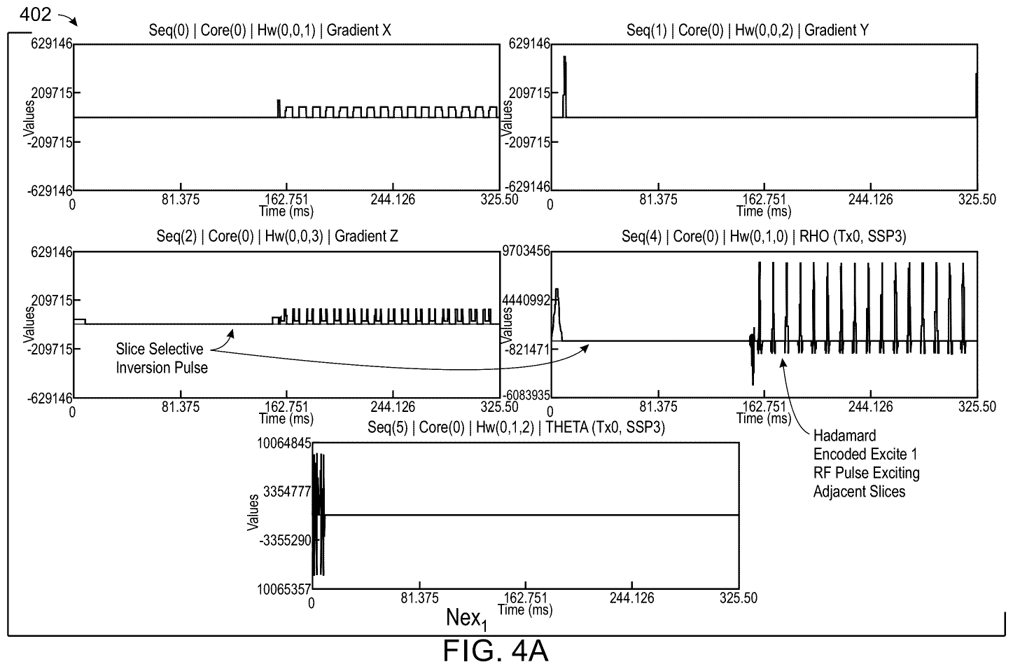

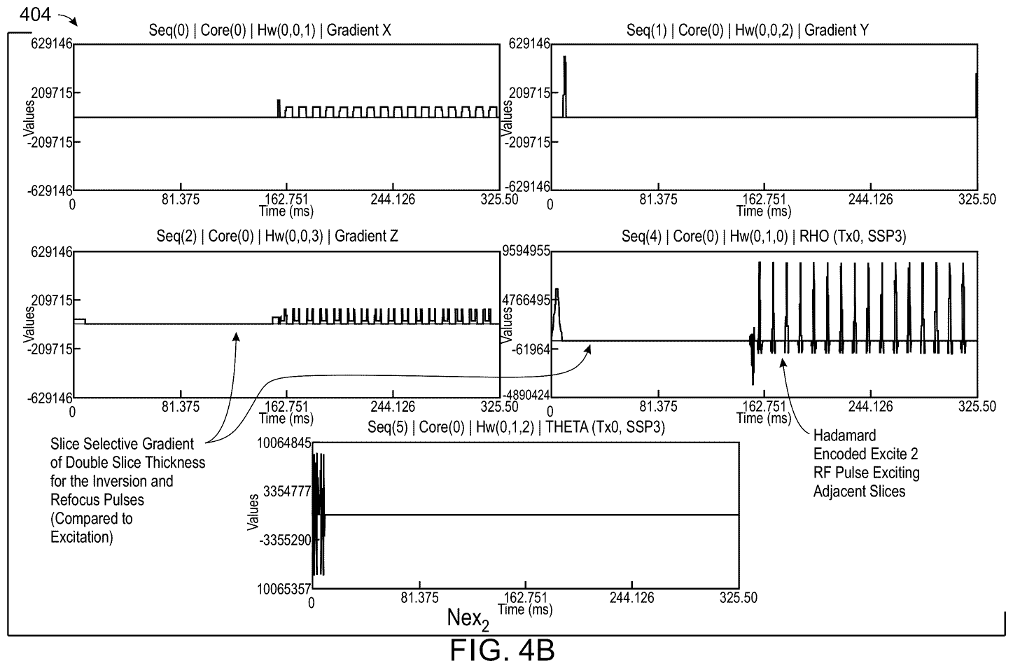

FIG. 4A and FIG. 4B illustrate two sets of pulse sequence diagrams 400 and 402 corresponding to NEX1 (single acquisition) and NEX2 (double acquisition), respectively (utilizing Hadamard encoded pulses and inversion recovery (IR) sequence). Both pulse sequence diagrams 400 and 402 also show Hadamard Encoded pulses. Thus, in one embodiment, the IR preparation module (with the proper inversion time for fat/fluid suppression) is applied to a pair of SMS Hadamard excited slices and the Hadamard decoding is applied for slice separation in a Fast Spin Echo sequence. This solves an unmet need in SMS which enables the use of IR Preparation in 2D or 3D SMS sequences. The SMS excited slices could be Hadamard or Hadamard like encoded and decoded. The excitation can be 2 Nex or 1 Nex for SMS encoding/decoding.

The inversion pulse is applied to prepare adjacent multiple slices by reducing the slice selection gradient. The technique can work with any coil (irrespective of the channel counts) and simplistic design. The technique is adaptable to other inversion prepped sequences like T1 FLAIR, T2 FLAIR which have prolonged scan times. The technique also works good for contrast-based inversion prepped cardiac sequences.

The Inversion Prepped SMS Hadamard encoded technique applied on adjacent slices is adaptable to the existing adiabatic inversion pulses. Current SMS techniques (Multiband) would have required multi-banding the complex adiabatic pulse to inversion prepare multiple slices that are far apart (SAR restrained pulses, adiabatic property loss, improper flip angles, need for RF stretching or gradient verse are possible issues with Multiband Inversion Recovery in addition to complex cross-talk over multiple TRs). Other inversion preparation schemes require the use of non-selective and slab inversion pulses to excite a big slab. Performing SMS excitation on these kind of prepped sequences gives a slightly different TI for each slice.

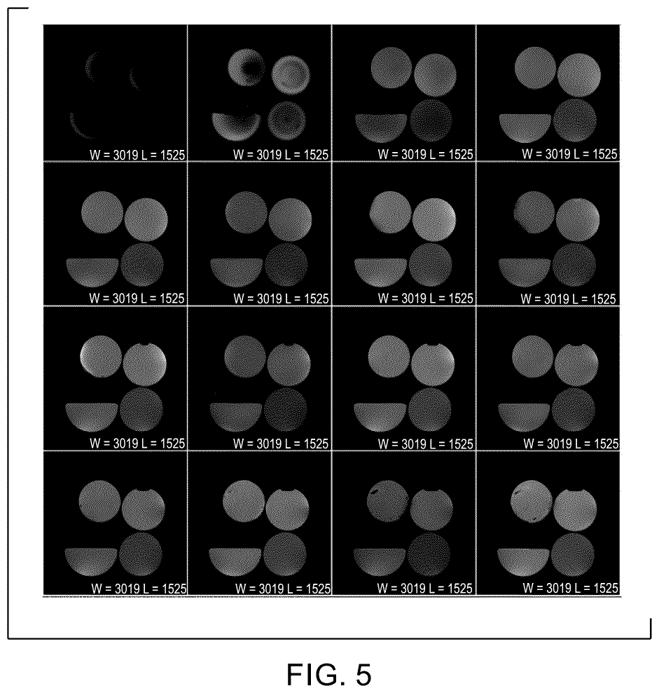

FIG. 5 depicts an axial images of a fat/water phantom acquired using Inversion Prepared SMS Hadamard encoded excitation. The axial images include 16 slices utilizing 2 nex of the fat/water phantom. The axial images show uniform fat suppression across the slices using Inversion Prepared SMS Hadamard encoded excitation.

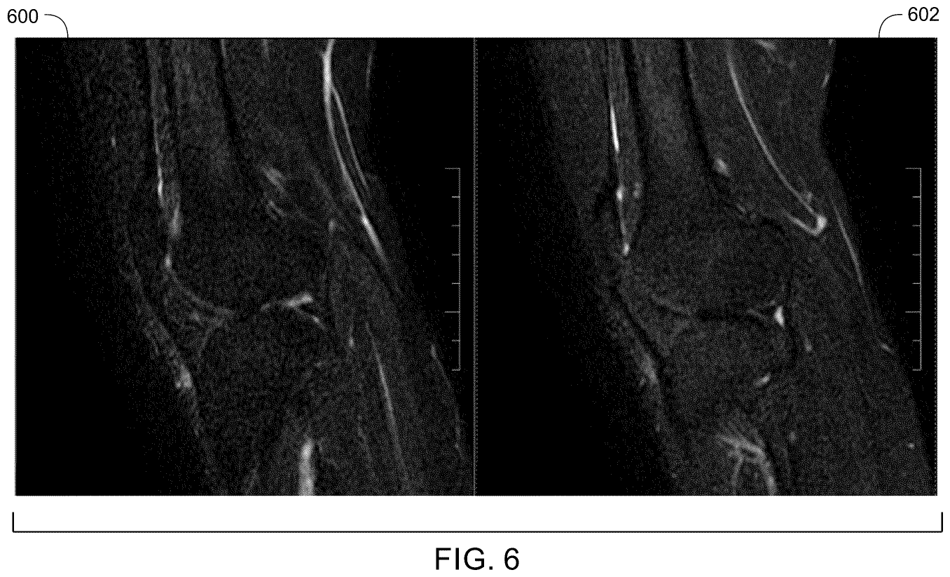

FIG. 6 depicts a comparison of images 600, 602 acquired of a knee of a subject. Image 600 was acquired without using the Hadamard encoded excitation processing technique. Image 602 was acquired using the Hadamard encoded excitation processing technique. Image 600 shows artifacts in the human knee scan, whereas the other image 602 shows the same knee scan with reduced artifacts due to using the Hadamard encoded excitation processing technique.

Technical effects of the disclosed embodiments are that the MR scan is faster due to scan time reduction, the acquisition is cheaper as the existing hardware that runs multiband on scanners could be used more efficiently. Further, the MR scan is safer as Hadamard or Hadamard like encoding is adding peak B1/SAR only to the multibanded excitation pulses while the refocusing multibanded pulses are not touched.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

The disclosure also provides support for a computer-implemented method for generating a magnetic resonance (MR) image of an object, comprising: applying, via a processing system comprising one or more processors, a Hadamard encoded radiofrequency (RF) excitation pulse sequence to adjacent slices within a magnetic resonance imaging (MRI) scanner to generate Hadamard encoded adjacent slices; multiplexing, via the processing system, the Hadamard encoded adjacent slices with secondary RF excitation pulses to generate a composite RF pulse; and generating, via the processing system, the MR image of the object using the composite RF pulse. In a first example of the computer-implemented method, the secondary RF excitation pulses comprise multiband RF excitation pulses or an inversion recovery (IR) sequence. In a second example of the computer-implemented method, optionally including the first example, the secondary RF excitation pulses comprise the multiband RF excitation pulses, and wherein the Hadamard encoded RF excitation pulse sequence and the multiband RF excitation pulses are frequency multiplexed using the Larmor frequency of nearby slices for the Hadamard encoded RF excitation pulses and the Larmor frequency of far-away slices for the multiband RF excitation pulses. In a third example of the computer-implemented method, optionally including one or both of the first and second examples, the secondary RF excitation pulses comprise the IR sequence, and wherein the IR sequence employs an increased slice thickness for the purpose of inverting or preparing the Hadamard encoded adjacent slices. In a fourth example of the computer-implemented method, optionally including one or more or each of the first through third examples, the IR sequence is followed by Hadamard encoded Cartesian or Propeller or Radial or Spiral readout. In a fifth example of the computer-implemented method, optionally including one or more or each of the first through fourth examples, wherein the secondary RF excitation pulses comprise the IR sequence, and wherein the IR sequence employs an adiabatic or non-adiabatic pulse to invert or prepare the Hadamard encoded adjacent slices. In a sixth example of the computer-implemented method, optionally including one or more or each of the first through fifth examples, the composite RF pulse is employed to accelerate a diffusion, perfusion or functional MRI scans with echo planar imaging (EPI) readout. In a seventh example of the computer-implemented method, optionally including one or more or each of the first through sixth examples, the computer-implemented method further comprises utilizing, via the processing system, parallel imaging techniques with the composite RF pulse to increase total acceleration factors of the MRI scan. In an eighth example of the computer-implemented method, optionally including one or more or each of the first through the seventh examples, the parallel imaging techniques comprise at least one of Autocalibrating Reconstruction for Cartesian imaging (ARC), GeneRalized Autocalibrating Partially Parallel Acquisitions (GRAPPA), Sensitivity Encoding (SENSE), Array coil Spatial Sensitivity Encoding (ASSET) or Compressed Sensing. In a ninth example of the computer-implemented method, optionally including one or more or each of the first through eight examples, the computer-implemented method further comprises applying, via the processing system, a slice selection gradient for refocusing pulses that is half the regular slice gradient. In a tenth example of the computer-implemented method, optionally including one or more or each of the first through ninth examples, the computer-implemented method further comprises decoding, via the processing system, the Hadamard encoded pulses and the secondary encoded pulses in a reconstruction process to produce a composite magnetic resonance (MR) signal. In an eleventh example of the computer-implemented method, optionally including one or more or each of the first through tenth examples, further comprising utilizing, via the processing system, a pair of simultaneous multi-slice (SMS) with the composite RF pulse to increase total acceleration factors of the MRI scan. In a twelfth example of the computer-implemented method, optionally including one or more or each of the first through eleventh examples, the SMS excited slices are encoded and decoded using Hadamard or Hadamard-like factors. In a thirteenth example of the computer-implemented method, optionally including one or more or each of the first through twelfth examples, the encoding and decoding is performed using a single average or multiple averages for Hadamard encoding and decoding.

The disclosure also provides support for a system for generating a magnetic resonance (MR) image of an object, comprising: a memory encoding processor-executable routines; and a processing system comprising one or more processors and configured to access the memory and to execute the processor-executable routines, wherein the processor-executable routines, when executed by the processing system, cause the processing system to: apply a Hadamard encoded radiofrequency (RF) excitation pulse sequence to adjacent slices within a magnetic resonance imaging (MRI) scanner to generate Hadamard encoded adjacent slices; multiplex the Hadamard encoded adjacent slices with secondary RF excitation pulses to generate a composite RF pulse; and generate the MR image of the object using the composite RF pulse. In a first example of the system, the secondary RF excitation pulses comprise multiband RF excitation pulses or an inversion recovery (IR) sequence. In a second example of the system, optionally including the first example, the secondary RF excitation pulses comprise the multiband RF excitation pulses, and wherein the Hadamard encoded RF excitation pulse sequence and the multiband RF excitation pulses are frequency multiplexed using the Larmor frequency of nearby slices for the Hadamard encoded RF excitation pulses and the Larmor frequency of far-away slices for the multiband RF excitation pulses. In a third example of the system, optionally including one or both of the first and second examples, the secondary RF excitation pulses comprise the IR sequence, and wherein the IR sequence employs an increased slice thickness for the purpose of inverting or preparing the Hadamard encoded adjacent slices. In a fourth example of the system, optionally including one or more or each of the first through third examples, the IR sequence is followed by Hadamard encoded Cartesian or Propeller or Radial or Spiral readout.

The disclosure also provides support for a non-transitory computer-readable medium, the non-transitory computer-readable medium comprising processor-executable code that when executed by a processing system comprising one or more processors, causes the processing system to: apply a Hadamard encoded radiofrequency (RF) excitation pulse sequence to adjacent slices within a magnetic resonance imaging (MRI) scanner to generate Hadamard encoded adjacent slices; multiplex the Hadamard encoded adjacent slices with secondary RF excitation pulses to generate a composite RF pulse; and generate a magnetic resonance (MR) image of an object using the composite RF pulse.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A computer-implemented method for generating a magnetic resonance (MR) image of an object, comprising:
applying, via a processing system comprising one or more processors, a Hadamard encoded radiofrequency (RF) excitation pulse sequence to adjacent slices within a magnetic resonance imaging (MRI) scanner to generate Hadamard encoded adjacent slices;
multiplexing, via the processing system, the Hadamard encoded adjacent slices with secondary RF excitation pulses to generate a composite RF pulse; and
generating, via the processing system, the MR image of the object using the composite RF pulse.

2. The computer-implemented method of claim 1, wherein the secondary RF excitation pulses comprise multiband RF excitation pulses or an inversion recovery (IR) sequence.

3. The computer-implemented method of claim 2, wherein the secondary RF excitation pulses comprise the multiband RF excitation pulses, and wherein the Hadamard encoded RF excitation pulse sequence and the multiband RF excitation pulses are frequency multiplexed using the Larmor frequency of nearby slices for the Hadamard encoded RF excitation pulses and the Larmor frequency of far-away slices for the multiband RF excitation pulses.

4. The computer-implemented method of claim 2, wherein the secondary RF excitation pulses comprise the IR sequence, and wherein the IR sequence employs an increased slice thickness for the purpose of inverting or preparing the Hadamard encoded adjacent slices.

5. The computer-implemented method of claim 4, wherein the IR sequence is followed by Hadamard encoded Cartesian or Propeller or Radial or Spiral readout.

6. The computer-implemented method of claim 2, wherein the secondary RF excitation pulses comprise the IR sequence, and wherein the IR sequence employs an adiabatic or non-adiabatic pulse to invert or prepare the Hadamard encoded adjacent slices.

7. The computer-implemented method of claim 1, wherein the composite RF pulse is employed to accelerate a diffusion scan, a perfusion scan, or a functional MRI scans with echo planar imaging (EPI) readout.

8. The computer-implemented method of claim 1, further comprising utilizing, via the processing system, parallel imaging techniques with the composite RF pulse to increase total acceleration factors of the MRI scan.

9. The computer-implemented method of claim 8, wherein the parallel imaging techniques comprise at least one of Autocalibrating Reconstruction for Cartesian imaging (ARC), GeneRalized Autocalibrating Partially Parallel Acquisitions (GRAPPA), Sensitivity Encoding (SENSE), Array coil Spatial Sensitivity Encoding (ASSET) or Compressed Sensing.

10. The computer-implemented method of claim 1, further comprising applying, via the processing system, a slice selection gradient for refocusing pulses that is half the regular slice gradient.

11. The computer-implemented method of claim 1, further comprising decoding, via the processing system, the Hadamard encoded pulses and the secondary encoded pulses in a reconstruction process to produce a composite magnetic resonance (MR) signal.

12. The computer-implemented method of claim 1, further comprising utilizing, via the processing system, a pair of simultaneous multi-slice (SMS) excited slices with the composite RF pulse to increase total acceleration factors of the MRI scan.

13. The computer-implemented method of claim 12, wherein the SMS excited slices are encoded and decoded using Hadamard or Hadamard-like factors.

14. The computer-implemented method of claim 13, wherein the encoding and decoding is performed using a single average or multiple averages for Hadamard encoding and decoding.

15. A system for generating a magnetic resonance (MR) image of an object, comprising:
a memory encoding processor-executable routines;
a processing system comprising one or more processors and configured to access the memory and to execute the processor-executable routines, wherein the processor-executable routines, when executed by the processing system, cause the processing system to:
apply a Hadamard encoded radiofrequency (RF) excitation pulse sequence to adjacent slices within a magnetic resonance imaging (MRI) scanner to generate Hadamard encoded adjacent slices;
multiplex the Hadamard encoded adjacent slices with secondary RF excitation pulses to generate a composite RF pulse; and
generate the MR image of the object using the composite RF pulse.

16. The system of claim 15, wherein the secondary RF excitation pulses comprise multiband RF excitation pulses or an inversion recovery (IR) sequence.

17. The system of claim 16, wherein the secondary RF excitation pulses comprise the multiband RF excitation pulses, and wherein the Hadamard encoded RF excitation pulse sequence and the multiband RF excitation pulses are frequency multiplexed using the Larmor frequency of nearby slices for the Hadamard encoded RF excitation pulses and the Larmor frequency of far-away slices for the multiband RF excitation pulses.

18. The system of claim 16, wherein the secondary RF excitation pulses comprise the IR sequence, and wherein the IR sequence employs an increased slice thickness for the purpose of inverting or preparing the Hadamard encoded adjacent slices.

19. The system of claim 18, wherein the IR sequence is followed by Hadamard encoded Cartesian or Propeller or Radial or Spiral readout.

20. A non-transitory computer-readable medium, the computer-readable medium comprising processor-executable code that when executed by a processing system comprising one or more processors, causes the processing system to:
apply a Hadamard encoded radiofrequency (RF) excitation pulse sequence to adjacent slices within a magnetic resonance imaging (MRI) scanner to generate Hadamard encoded adjacent slices;
multiplex the Hadamard encoded adjacent slices with secondary RF excitation pulses to generate a composite RF pulse; and
generate a magnetic resonance (MR) image of an object using the composite RF pulse.
